(19) United States
(12) Patent Application Publication
(10) Pub. No.: US 2024/0008175 A1
(43) Pub. Date: Jan. 4, 2024

(54) PRINTED WIRING BOARD AND METHOD OF MANUFACTURING PRINTED WIRING BOARD

(71) Applicants: SUMITOMO ELECTRIC INDUSTRIES, LTD., Osaka (JP); SUMITOMO ELECTRIC PRINTED CIRCUITS, INC., Shiga (JP)

(72) Inventors: Yoshio OKA, Osaka (JP); Koji NITTA, Osaka (JP); Shoichiro SAKAI, Osaka (JP)

(73) Assignees: SUMITOMO ELECTRIC INDUSTRIES, LTD., Osaka (JP); SUMITOMO ELECTRIC PRINTED CIRCUITS, INC., Shiga (JP)

(21) Appl. No.: 18/037,911

(22) PCT Filed: Jun. 7, 2022
(86) PCT No.: PCT/JP2022/022932

§ 371 Date: May 19, 2023

(30) Foreign Application Priority Data
Jul. 20, 2021 (JP) 2021-119547

(51) Int. Cl. H05K 1/02; H05K 3/10

(52) U.S. Cl. CPC H05K 1/0298; H05K 3/10; H05K 2201/068

(57) ABSTRACT

A printed wiring board includes a base film having a first surface and a second surface opposite to the first surface, a first electrically conductive pattern existing on the first surface, and a first electrically insulating layer existing on the first surface so as to cover the first electrically conductive pattern. A plurality of first voids exist in the first electrically insulating layer.

The present disclosure relates to a printed wiring board and a method of manufacturing a printed wiring board. This application claims priority based on Japanese Patent Application No. 2021-119547 filed on Jul. 20, 2021, and the entire contents of the Japanese patent application are incorporated herein by reference.

### BACKGROUND

Japanese Unexamined Patent Application Publication No. 2016-9854 (PTL 1) describes a printed wiring board. The printed wiring board described in PTL 1 includes a base film, a conductive pattern, and an adhesive layer (insulating layer). The base film has a main surface. The conductive pattern is on a main surface of the base film. The insulating layer covers the conductive pattern on the main surface of the base film.

### PRIOR ART DOCUMENT

### Patent Literature

PTL 1: Japanese Unexamined Patent Application Publication No. 2016-9854

### SUMMARY OF INVENTION

A printed wiring board of the present disclosure includes a base film having a first surface and a second surface opposite to the first surface, a first electrically conductive pattern existing on the first surface, and a first electrically insulating layer existing on the first surface so as to cover the first electrically conductive pattern. A plurality of first voids exist in the first electrically insulating layer.

A method of manufacturing a printed wiring board of the present disclosure includes preparing a base film having a first surface and a second surface opposite to the first surface, forming a first electrically conductive pattern on the first surface, and forming a first electrically insulating layer on the first surface so as to cover the first electrically conductive pattern. Forming the first electrically insulating layer includes providing a plurality of first voids in the first electrically insulating layer.

### BRIEF DESCRIPTION OF THE DRAWINGS

FIG. 1 is a plan view of a printed wiring board 100.

FIG. 2 is a bottom plan view of printed wiring board 100,

FIG. 3A is a cross-sectional view taken along line IIIA-IIIA of FIG. 1.

FIG. 3B is a cross-sectional view taken along line of FIG. 1.

FIG. 4 is a flow chart showing a method of manufacturing printed wiring board 100.

FIG. 5 is a cross-sectional view of printed wiring board 100 after a first layer formation step S21a is performed.

FIG. 6 is a cross-sectional view of printed wiring board 100 after a through hole formation step S21b is performed.

FIG. 7A is a first cross-sectional view of printed wiring board 100 after a second layer formation step S21c is performed.

FIG. 7B is a second cross-sectional view of printed wiring board 100 after second layer formation step S21c is performed.

FIG. 8A is a first cross-sectional view of printed wiring board 100 after a resist formation step S22 is performed.

FIG. 8B is a second cross-sectional view of printed wiring board 100 after resist formation step S22 is performed.

FIG. 9A is a first cross-sectional view of printed wiring board 100 after a first electrolytic plating step S23 is performed.

FIG. 9B is a second cross-sectional view of printed wiring board 100 after first electrolytic plating step S2.3 is performed.

FIG. 10A is a first cross-sectional view of printed wiring board 100 after a resist removal step S24 is performed.

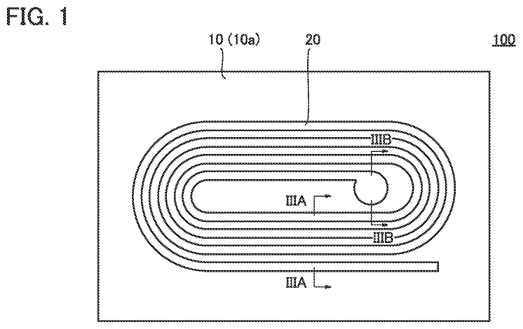

FIG. 1.0B is a second cross-sectional view of printed wiring board 100 after resist removal step S24 is performed.

FIG. 11A is a first cross-sectional view of printed wiring board 100 after a seed layer removal step S25 is performed.

FIG. 11B is a second cross-sectional view of printed wiring board 100 after seed layer removal step S25 is performed.

FIG. 12A is a first cross-sectional view of printed wiring board 100 after a second electrolytic plating step S26 is performed.

FIG. 12B is a second cross-sectional view of printed wiring board 100 after second electrolytic plating step S26 is performed.

### DETAILED DESCRIPTION

### Problems to be Solved by Present Disclosure

It is preferable to use a resin material having high heat resistance (that is, a high glass transition point) for the insulating layer covering the conductive pattern. However, a resin material having high heat resistance tends to have a large elastic modulus. Therefore, when a resin material having high heat resistance (large elastic modulus) is used for the insulating layer covering the conductive pattern, there is a possibility that the warpage of the printed wiring board due to the temperature rise becomes large.

The present disclosure has been made in view of the problems of the prior art as described above. More specifically, it is an object of the present invention to provide a printed wiring board and a method of manufacturing the printed wiring board, which are capable of suppressing warpage caused by a temperature rise.

### Advantageous Effects of Present Disclosure

According to the printed wiring board and the method of manufacturing the printed wiring board of the present disclosure, it is possible to suppress warpage caused by a temperature rise.

### DESCRIPTION OF EMBODIMENTS OF PRESENT DISCLOSURE

First, embodiments of the present disclosure will be listed and explained.

(1) A printed wiring board according to an embodiment includes a base film having a first surface and a second surface opposite to the first surface, a first first electrically conductive pattern existing on the first surface, and a first electrically insulating layer existing on the first surface so as to cover the first electrically conductive pattern. A plurality of first voids exist in the first electrically insulating layer. According to the printed wiring board of the above (1), it is possible to suppress warpage caused by a temperature rise.

(2) In the printed wiring board of the above (1), an area ratio of the plurality of first voids in the first electrically insulating layer in a sectional view may be 3 percent or more. According to the printed wiring board of the above (2), it is possible to further suppress the warpage caused by a temperature rise.

(3) In the printed wiring board of the above (1) or (2), a coefficient of thermal expansion of the first electrically insulating layer may be 3.0×10⁻⁵/K or more. According to the printed wiring board of the above (3), even when the coefficient of thermal expansion of the first electrically insulating layer is large, it is possible to suppress the warpage caused by a temperature rise.

(4) In the printed wiring board of the above (1) to (3), an elastic modulus of the first electrically insulating layer may be 2 GPa or more. According to the printed wiring board of the above (4), heat resistance can be enhanced.

(5) In the printed wiring board of the above (1) to (4), the first electrically conductive pattern may have a first seed layer existing on the first surface, a first core body existing on the first seed layer, and a first shrink layer covering the first core body. According to the printed wiring board of the above (5), the pattern rate of the first electrically conductive pattern can be increased.

(6) In the printed wiring board of the above (1) to (5), a height of the first electrically conductive pattern may be larger than a width of the first electrically conductive pattern. According to the printed wiring board of the above (6), it is possible to reduce the wiring resistance of the first electrically conductive pattern.

(7) In the printed wiring board of the above (1) to (6), a height of the first electrically conductive pattern may be larger than a thickness of the base film.

(8) In the printed wiring board of the above (1) to (7), the first electrically conductive pattern may have a spiral shape in a plan view. According to the printed wiring board of the above (8), it is possible to reduce the deviation of the direction of the warpage caused by a temperature rise.

(9) The printed wiring board of the above (1) to (8) may further include a second electrically conductive pattern existing on the second surface, and a second electrically insulating layer existing on the second surface so as to cover the second electrically conductive pattern. A plurality of second voids may exist in the second electrically insulating layer. A value obtained by dividing a total area of the first electrically conductive pattern by an area of the first surface in a plan view may differ from a value obtained by dividing a total area of the second electrically conductive pattern by an area of the second surface in a plan view.

(10) A method of manufacturing a printed wiring board according to an embodiment includes preparing a base film having a first surface and a second surface opposite to the first surface, forming a first electrically conductive pattern on the first surface, and forming a first electrically insulating layer on the first surface so as to cover the first electrically conductive pattern. Forming the first electrically insulating layer includes providing a plurality of first voids in the first electrically insulating layer. According to the method of manufacturing a printed wiring board of the above (10), it is possible to suppress warpage.

(11) In the method of manufacturing a printed wiring board of the above (10), forming the first electrically insulating layer may include introducing a hollow microcapsule into an unhardened electrically insulating material, applying the electrically insulating material to the first surface so as to cover the first electrically conductive pattern, and heating and hardening the electrically insulating material.

### DETAILS OF EMBODIMENTS OF PRESENT DISCLOSURE

The details of embodiments of the present disclosure are be described with reference to the drawings. In the following drawings, the same or corresponding parts are denoted by the same reference numerals, and redundant description will not be repeated.

### Configuration of Printed Wiring Board According to Embodiment

Hereinafter, a printed wiring board (referred to as “printed wiring board 100”) according to an embodiment will be described.

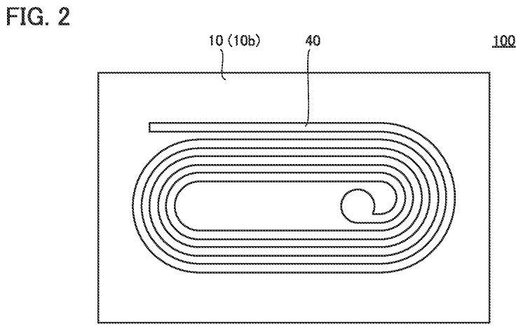

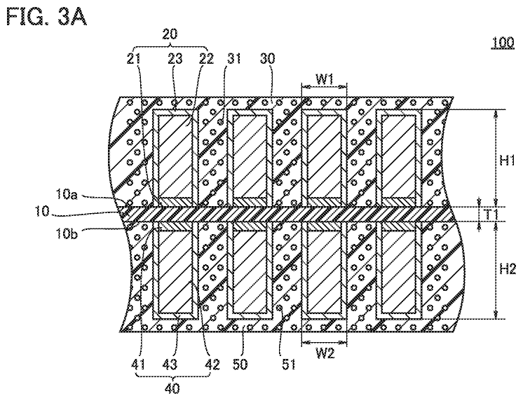

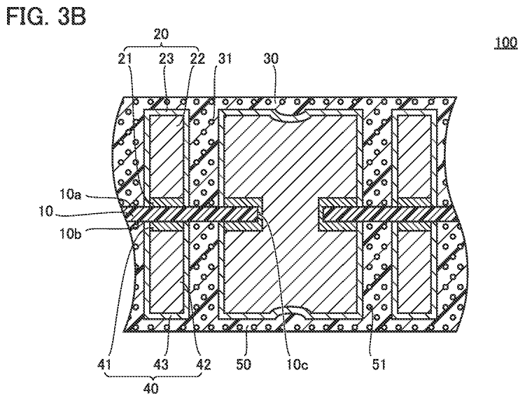

FIG. 1 is a plan view of printed wiring board 100. FIG. 2 is a bottom plan view of printed wiring board 100. In FIGS. 1 and 2, a first electrically insulating layer 30 and a second electrically insulating layer 50 are not shown. FIG. 3A is a cross-sectional view taken along line MA-MA of FIG. 1. FIG. 3B is a cross-sectional view taken along line IIIB-IIIB of FIG. 1. As shown in FIGS. 1, 2, 3A and 3B, printed wiring board 100 includes a base film 10, a first electrically conductive pattern 20, first electrically insulating layer a second electrically conductive pattern 40, and second electrically insulating layer 50.

Base film 10 has a first surface 10a and a second surface 10b. First surface 10a and second surface 10b are main surfaces of base film 10. Second surface 10b is a surface opposite to first surface 10a. A through hole 10c is formed in base film 10. Through hole passes through base film 10 in the thickness direction.

The thickness of base film 10 is referred to as a thickness T1. Thickness T1 is preferably 50 μm or less. Thickness T1 is more preferably 20 μm or less. Accordingly, it is possible to increase the volume ratio of first electrically conductive pattern 20 and second electrically conductive pattern 40. Base film 10 is formed of a flexible insulating resin material. That is, printed wiring board 100 is a flexible printed wiring board. Specific examples of the material constituting base film 10 include polyimide, polyethylene terephthalate, and fluororesin.

First electrically conductive pattern 20 is disposed on first surface 10a. First electrically conductive pattern 20 has a spiral shape in a plan view (when viewed in a direction orthogonal to first surface 10a). That is, first electrically conductive pattern 20 constitutes a coil.

First electrically conductive pattern 20 includes, for example, a first seed layer 21, a first core body 22, and a first shrink layer 23.

First seed layer 21 is on first surface 10a. First seed layer 21 includes, for example, a first layer and a second layer. The first layer of first seed layer 21 is on first surface 10a. The first layer of first seed layer 21 is formed of, for example, a nickel-chromium alloy. Copper may be formed on the nickel-chromium alloy. The first layer of first seed layer 21 is, for example, a sputtered layer. The second layer of first seed layer 21 is on the first layer of first seed layer 21. The second layer of first seed layer 21 is formed of, for example, copper. The second layer of first seed layer 21 is, for example, a sputtered layer, an electroless plating layer, or a layer in which a sputtered layer and an electroless plating layer are stacked.

First core body 22 is on first seed layer 21. First core body 22 is formed of, for example, copper. First core body 22 is, for example, an electrolytic plating layer. First shrink layer 23 covers the side surfaces of first seed layer 21 and first core body 22 and the upper surface of first core body 22. First shrink layer 23 is, for example, an electrolytic plating layer.

The width of first electrically conductive pattern 20 is referred to as a width W1, and the height of first electrically conductive pattern 20 is referred to as a height H1. Height H1 is, for example, larger than width W1. That is, an aspect ratio (a value obtained by dividing height H1 by width W1) of first electrically conductive pattern 20 is, for example, 1 or more. The aspect ratio of first electrically conductive pattern 20 is preferably 1.5 or more. Height H1, is, for example, more than or equal to thickness T1. Height H1 is, for example, 40 μm or more.

A value obtained by dividing the total area of first electrically conductive pattern 20 by the area of a region sandwiched between the innermost periphery and the outermost periphery of first electrically conductive pattern 20 is defined as a first pattern ratio. The first pattern ratio is, for example, 30 percent or more. The first pattern ratio may be 40 percent or more.

First electrically insulating layer 30 is on first surface 10a so as to cover first electrically conductive pattern 20. First electrically insulating layer 30 is formed of an insulating resin material, Specific examples of the material constituting first electrically insulating layer 30 include epoxy, urethane and polyimide.

The elastic modulus of first electrically insulating layer 30 is, for example, 2 GPa or more, Thus, the heat resistance of printed wiring board 100 can be enhanced. The elastic modulus of first electrically insulating layer 30 may be 4 GPa or more. The elastic modulus of first electrically insulating layer 30 is the elastic modulus of the constituent material of first electrically insulating layer 30. The elastic modulus of first electrically insulating layer 30 is, for example, 12 GPa or less. The elastic modulus of first electrically insulating layer 30 is measured by the nanoindentation method defined in ISO14577.

The coefficient of thermal expansion of first electrically insulating layer 30 is, for example, 3.0×10⁻⁵/K or more. As a result, even when the coefficient of thermal expansion of first electrically insulating layer 30 is large, warpage of printed wiring board 100 due to a temperature rise can be suppressed by providing first voids 31. The coefficient of thermal expansion of first electrically insulating layer 30 may be 4.5×10⁻⁵/K or more. The coefficient of thermal expansion of first electrically insulating layer 30 is, for example, 9.0×10⁻⁵/K or less. The coefficient of thermal expansion of first electrically insulating layer 30 may be 2.0×10⁻⁴/K or less. By setting the coefficient of thermal expansion of first electrically insulating layer 30 within such a range, it is possible to sufficiently suppress the warpage of printed wiring board 100 due to a temperature rise by providing first voids 31. The coefficient of thermal expansion of first electrically insulating layer 30 is the coefficient of thermal expansion of the material of first electrically insulating layer 30. The coefficient of thermal expansion of first electrically insulating layer 30 is measured by TMA (Thermal Mechanical Analysis).

A plurality of first voids 31 are present in first electrically insulating layer 30. First voids 31 are present between at least adjacent portions of first electrically conductive pattern 20. First void 31 has, for example, a spherical shape. However, the shape of first void 31 is not limited thereto.

In the sectional view, an area ratio of the plurality of first voids 31 in first electrically insulating layer 30 is, for example, 3 percent or more. Accordingly, it is possible to further suppress the warpage of printed wiring board 100 caused by the temperature rise. In the sectional view, an area ratio of the plurality of first voids 31 in first electrically insulating layer 30 may be 5 percent or more. In the sectional view, an area ratio of the plurality of first voids 31 in first electrically insulating layer 30 is, for example, 30 percent or less. The area ratio of the plurality of first voids 31 in first electrically insulating layer 30 in the sectional view is calculated by acquiring a cross-sectional image of first electrically insulating layer 30 using a microscope (an optical microscope or an electron microscope) and performing image processing on the acquired cross-sectional image.

The average diameter of the plurality of first voids 31 is, for example, 5 μm or less. In this way, it is possible to increase the insulation between adjacent portions of first electrically conductive pattern 20. The average diameter of the plurality of first voids 31 is, for example, 0.3 μm or more. Thus, the number of the plurality of first voids 31 in first electrically insulating layer 30 can be reduced, and the manufacturing cost can be reduced. The average diameter of the plurality of first voids 31 is calculated by the following method.

When calculating the average diameter of the plurality of first voids 31, first, a cross-sectional image of first electrically insulating layer 30 is acquired using a microscope (optical microscope or electron microscope). Second, image processing is performed on the cross-sectional image to calculate the area of each of the plurality of first voids 31 included in the cross-sectional image. The square root of a value obtained by dividing the area of each of the plurality of first voids 31 included in the cross-sectional image by π/4 is the equivalent circle diameter of each of the plurality of first voids 31 included in the cross-sectional image. Third, a value obtained by dividing the sum of the equivalent circle diameters of the plurality of first voids 31 included in the cross-sectional image by the sum of the number of the plurality of first voids 31 included in the cross-sectional image is regarded as the average diameter of the plurality of first voids 31.

A microcapsule 32 (not shown) may be present on the surface of first void 31. Microcapsule 32 is hollow and is formed of an insulating resin material.

Second electrically conductive pattern 40 is disposed on second surface 10b. Second electrically conductive pattern 40 has a spiral shape in a plan view (when viewed in a direction orthogonal to second surface lob). That is, second electrically conductive pattern 40 constitutes a coil. Second electrically conductive pattern 40 is electrically connected to first electrically conductive pattern 20.

Second electrically conductive pattern 40 includes, for example, a second seed layer 41, a second core body 42, and a second shrink layer 43.

Second seed layer 41 is on second surface 10b. Second seed layer 41 includes, for example, a first layer and a second layer. The first layer of second seed layer 41 is on second surface 10b. The first layer of second seed layer 41 is formed of, for example, a nickel-chromium alloy. Copper may be formed on the nickel-chromium alloy. The first layer of second seed layer 41 is, for example, a sputtered layer. The second layer of second seed layer 41 is on the first layer of second seed layer 41. The second layer of second seed layer 41 is formed of, for example, copper. The second layer of second seed layer 41 is, for example, a sputtered layer, an electroless plating layer, or a layer in which a sputtered layer and an electroless plating layer are stacked.

Second core body 42 is on second seed layer 41. Second core body 42 is formed of, for example, copper. Second core body 42 is, for example, an electrolytic plating layer. Second shrink layer 43 covers the side surfaces of second seed layer 41 and second core body 42 and the upper surface of second core body 42. Second shrink layer 43 is, for example, an electrolytic plating layer.

The width of second electrically conductive pattern 40 is referred to as a width W2, and the height of second electrically conductive pattern 40 is referred to as a height H2. Height H2 is, for example, larger than width W2. That is, an aspect ratio (a value obtained by dividing height H2 by width W2) of second electrically conductive pattern 40 is, for example, 1 or more. The aspect ratio of second electrically conductive pattern 40 is preferably 1.5 or more. Height H2 is, for example, more than or equal to thickness T1. Height 112 is, for example, 40 μm or more.

A value obtained by dividing the total area of second electrically conductive pattern 40 by the area of a region sandwiched between the innermost periphery and the outermost periphery of second electrically conductive pattern 40 is defined as a second pattern ratio. The second pattern ratio is different from the first pattern ratio, for example. The second pattern ratio is, for example, higher than the first pattern ratio. The second pattern ratio is, for example, 40 percent or more. The second pattern ratio may be 50 percent or more.

The second layer of first seed layer 21 and the second layer of second seed layer 41 are connected to each other on the inner wall surface of through hole 10c. First core body 22 and second core body 42 are connected to each other on the inner wall surface of through hole 10c. First shrink layer 23 and second shrink layer 43 cover first core body 22 and second core body 42, respectively. Thus, first electrically conductive pattern 20 and second electrically conductive pattern 40 are electrically connected to each other.

Second electrically insulating layer 50 is on second surface 10b so as to cover second electrically conductive pattern 40. Second electrically insulating layer 50 is formed of an insulating resin material. Specific examples of the material constituting second electrically insulating layer 50 include epoxy, urethane and polyimide.

The elastic modulus of second electrically insulating layer 50 is, for example, 2 GPa or more. Thus, the heat resistance of printed wiring board 100 can be enhanced. The elastic modulus of second electrically insulating layer 50 may be 4 GPa or more. The elastic modulus of second electrically insulating layer 50 is, for example, 12 GPa or less. The elastic modulus of second electrically insulating layer 50 is the elastic modulus of the constituent material of second electrically insulating layer 50. The elastic modulus of second electrically insulating layer 50 is measured in the same manner as the elastic modulus of first electrically insulating layer 30.

The coefficient of thermal expansion of second electrically insulating layer 50 is for example 3.0×10⁻⁵/K or more. As a result, even when the coefficient of thermal expansion of second electrically insulating layer 50 is large, warpage of printed wiring board 100 due to temperature rise can be suppressed by providing a second void 51, The coefficient of thermal expansion of second electrically insulating layer 50 may be 4.5×10⁻⁵/K or more. The coefficient of thermal expansion of second electrically insulating layer 50 is, for example, 9.0×10⁻⁵/K or less. The coefficient of thermal expansion of second electrically insulating layer 50 may be 2.0×10⁻⁴ or less. By setting the coefficient of thermal expansion of second electrically insulating layer 50 within such a range, it is possible to sufficiently suppress the warpage of printed wiring board 100 due to a temperature rise by providing second void 51. The coefficient of thermal expansion of second electrically insulating layer 50 is the coefficient of thermal expansion of the constituent material of second electrically insulating layer 50. The coefficient of thermal expansion of second electrically insulating layer 50 is measured in the same manner as the coefficient of thermal expansion of first electrically insulating layer 30.

A plurality of second voids 51 are present in second electrically insulating layer Second voids 51 are present between at least adjacent portions of second electrically conductive pattern 40. Second void 51 has, for example, a spherical shape. However, the shape of second void 51 is not limited to this.

In the sectional view, an area ratio of the plurality of second voids 51 in second electrically insulating layer 50 is, for example, 3 percent or more. Accordingly, it is possible to further suppress the warpage of printed wiring board 100 caused by the temperature rise. In the sectional view, the area ratio of the plurality of second voids 51 in second electrically insulating layer 50 may be 5 percent or more. In the sectional view, the area ratio of the plurality of second voids 51 in second electrically insulating layer 50 is, for example, 30 percent or less. The area ratio of the plurality of second voids 51 in second electrically insulating layer 50 in the sectional view is measured in the same manner as the area ratio of the plurality of first voids 31 in first electrically insulating layer 30 in the sectional view.

The average diameter of the plurality of second voids 51 is, for example, 5 μm or less. In this way, it is possible to increase insulation between adjacent portions of second electrically conductive pattern 40. The average diameter of the plurality of second voids 51 is, for example, 0.3 μm or more. Thus, the number of the plurality of second voids 51 in second electrically insulating layer 50 can be reduced, and the manufacturing cost can be reduced. The average diameter of the plurality of second voids 51 is measured by the same method as the average diameter of the plurality of first voids 31. A microcapsule 52 (not shown) may be present on the surface of second void 51. Microcapsule 52 is hollow and is formed of an insulating resin material.

### Method of Manufacturing Printed Wiring Board According to Embodiment

Hereinafter, a method of manufacturing printed wiring board 100 will be described.

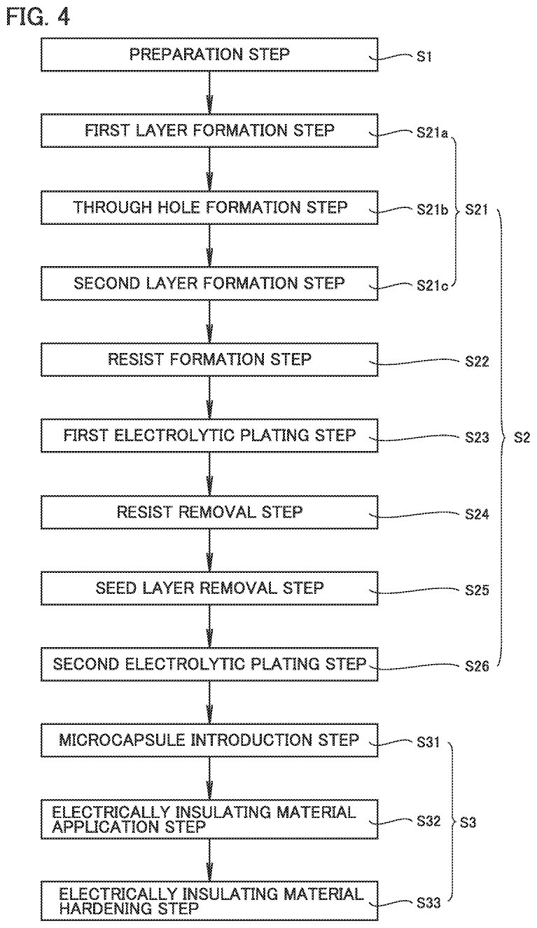

FIG. 4 is a flow chart showing a method of manufacturing printed wiring board 100. As shown in FIG. 4, the method of manufacturing printed wiring board 100 includes a preparation step S1, an electrically conductive pattern formation step S2, and an electrically insulating layer formation step S3.

In preparation step S1, base film 10 is prepared. Electrically conductive pattern formation step S2 is performed after preparation step S1. In electrically conductive pattern formation step S2, first electrically conductive pattern 20 and second electrically conductive pattern 40 are formed.

Electrically conductive pattern formation step S2 includes a seed layer formation step S21, a resist formation step S22, a first electrolytic plating step S23, a resist removal step S24, a seed layer removal step S25, and a second electrolytic plating step S26 Resist formation step S22 is performed after seed layer formation step S21. First electrolytic plating step S23 is performed after resist formation step S22. Resist removal step S24 is performed after first electrolytic plating step S23. Seed layer removal step S25 is performed after resist removal step S24. Second electrolytic plating step S26 is performed after seed layer removal step S25.

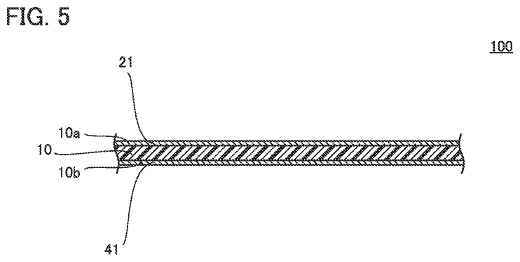

Seed layer formation step S21 includes a first layer formation step S21a, a through hole formation step S21b, and a second layer formation step S21c, FIG. 5 is a cross-sectional view of printed wiring board 100 after first layer formation step S21a is performed. As shown in FIG. 5, in first layer formation step S21a, the first layer of first seed layer 21 and the first layer of second seed layer 41 are formed. The first layer of first seed layer 21 and the first layer of second seed layer 41 are formed by performing sputtering on first surface 10a and second surface 10b, for example.

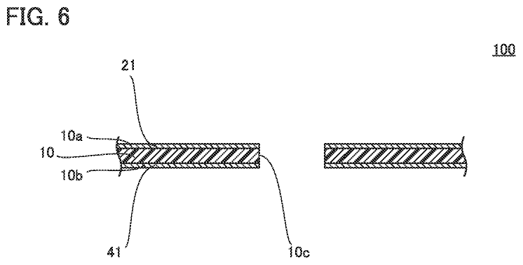

FIG. 6 is a cross-sectional view of printed wiring board 100 after through hole formation step S21b is performed. As shown in FIG. 6, in through hole formation step S21b, through hole 10c is formed. Through hole 10c is formed using, for example, a laser, a drill, or the like.

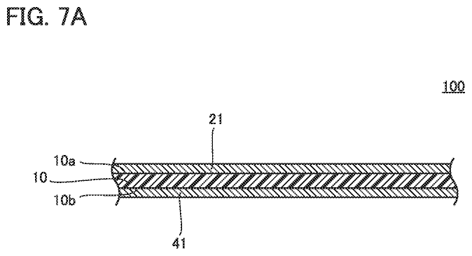

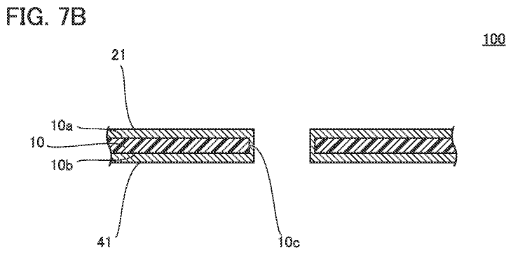

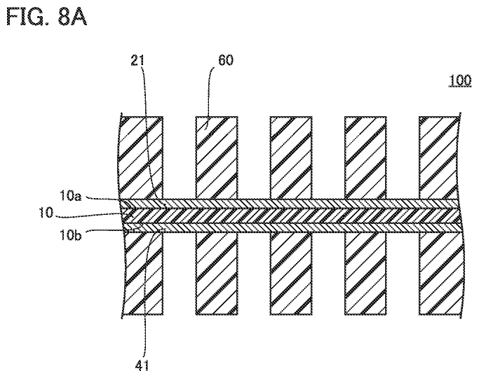

FIG. 7A is a first cross-sectional view of printed wiring board 100 after second layer formation step S21c is performed. FIG. 7B is a second cross-sectional view of printed wiring board 100 after second layer formation step S21c is performed. FIG. 7A is related to FIG. 3A and FIG. 7B is related to FIG. 3B. As shown in FIGS. 7A and 7B, in second layer formation step S21c—the second layer of first seed layer 21 and the second layer of second seed layer 41 are formed. For example, by performing electroless plating on the first layer of first seed layer 21, the first layer of second seed layer 41, and the inner wall surface of through hole 10c, the second layer of first seed layer 21 and the second layer of second seed layer 41 are formed.

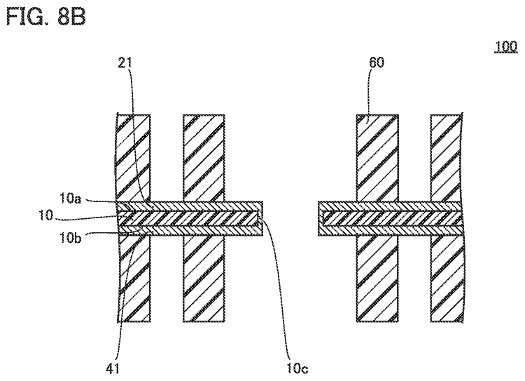

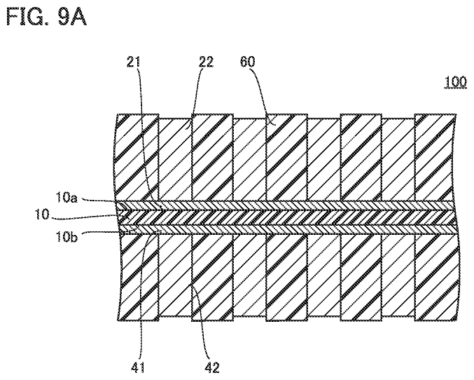

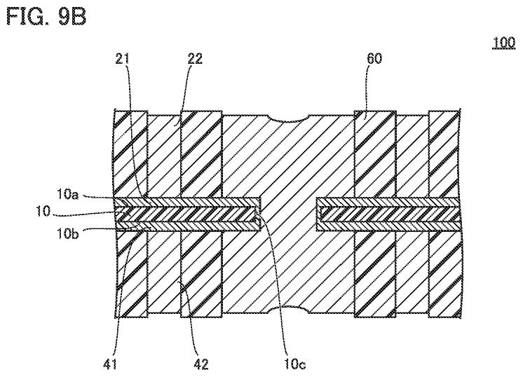

FIG. 8A is a first cross-sectional view of printed wiring board 100 after resist formation step S22 is performed. FIG. 8B is a second cross-sectional view of printed wiring board 100 after resist formation step S22 is performed. FIG. 8A is related to FIG. 3A and FIG. 8B is related to FIG. 3B. As shown in FIGS. 8A and 8B, in resist formation step S22, a resist 60 is formed on first seed layer 21 and second seed layer 41. In forming resist 60, first, a photosensitive organic material is applied on first seed layer 21 and second seed layer 41. Instead of applying the photosensitive organic material, a dry film resist may be disposed on first seed layer 21 and second seed layer 41. Second, resist 60 is formed by exposing and developing the applied photosensitive organic material (dry film resist) to perform patterning. First seed layer 21 and second seed layer 41 are partially exposed from resist 60.

FIG. 9A is a first cross-sectional view of printed wiring board 100 after first electrolytic plating step S23 is performed. FIG. 9B is a second cross-sectional view of printed wiring board 100 after first electrolytic plating step S23 is performed. FIG. 9A is related to FIG. 3A and FIG. 9B is related to FIG. 3B. As shown in FIGS. 9A and 9B, in first electrolytic plating step S23, first core body 22 and second core body 42 are formed. First core body 22 and second core body 42 are formed on first seed layer 21 and second seed layer 41 exposed from resist 60, respectively, by applying electric current to first seed layer 21 and second seed layer 41 to perform electrolytic plating.

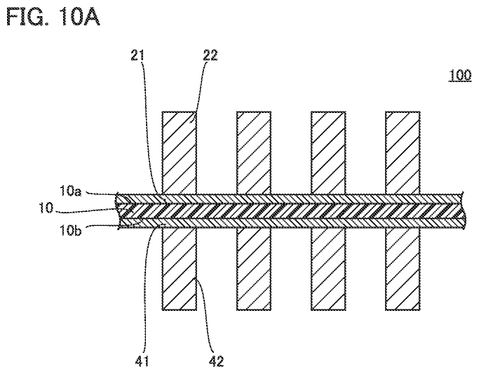

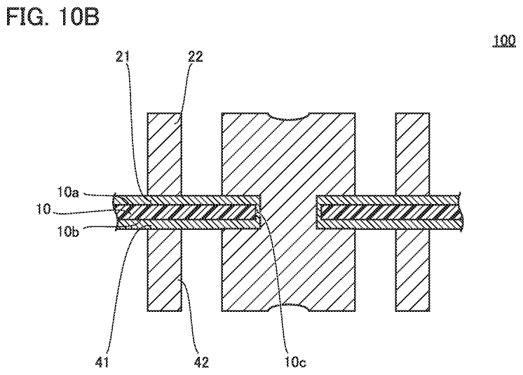

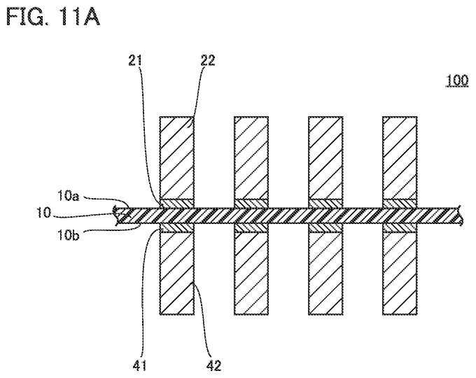

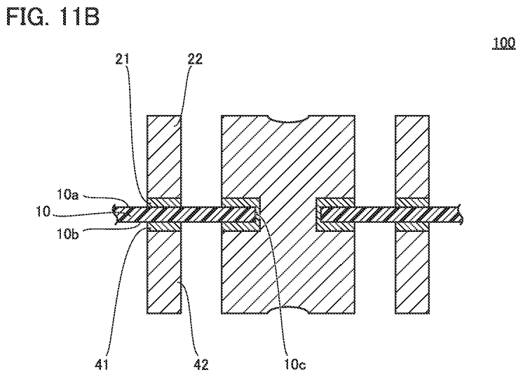

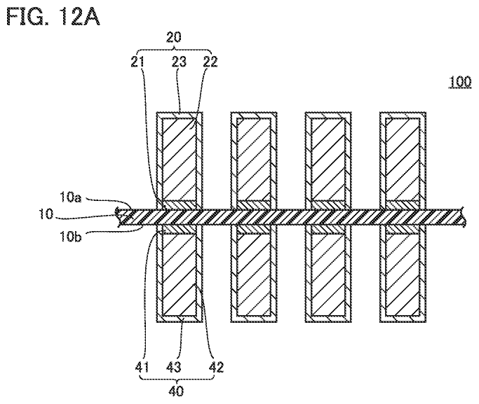

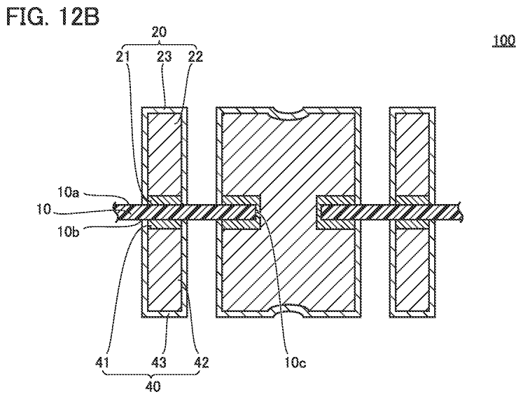

FIG. 10A is a first cross-sectional view of printed wiring board 100 after resist removal step S24 is performed. FIG. 10B is a second cross-sectional view of printed wiring board 100 after resist removal step S24 is performed. FIG. 11.0A is related to FIG. 3A and FIG. 10B is related to FIG. 3B. As shown in FIGS. 10A and 10B, in resist removal step S24, resist 60 is peeled off and removed from first seed layer 21 and second seed layer 41. After resist 60 is peeled off, first seed layer 21 is exposed between adjacent portions of first core body 22, and second seed layer 41 is exposed between adjacent portions of second core body 42.

FIG. 11A is a first cross-sectional view of printed wiring board 100 after seed layer removal step S25 is performed. FIG. 11B is a second cross-sectional view of printed wiring board 100 after seed layer removal step S25 is performed. FIG. 11A is related to FIG. 3A and FIG. 11B is related to FIG. 3B. As shown in FIGS. 11A and 11B, in seed layer removal step S25, first seed layer 21 exposed between adjacent portions of first core body 22 and second seed layer 41 exposed between adjacent portions of second core body 42 are removed by etching. This etching is, for example, wet etching.

FIG. 12A is a first cross-sectional view of printed wiring board 100 after second electrolytic plating step S26 is performed. FIG. 12B is a second cross-sectional view of printed wiring board 100 after second electrolytic plating step S26 is performed. FIG. 12A is related to FIG. 3A and FIG. 12B is related to FIG. 3B. As shown in FIGS. 12A and 12B, in second electrolytic plating step S26, first shrink layer 23 and second shrink layer 43 are formed.

First shrink layer 23 is formed so as to cover first seed layer 21 and first core body 22 by performing electrolytic plating by energizing first seed layer 21 and first core body 22. Second shrink layer 43 is formed so as to cover second seed layer 41 and second core body 42 by performing electrolytic plating by energizing second seed layer 41 and second core body 42.

Electrically insulating layer formation step S3 may be performed after electrically conductive pattern formation step S2. Electrically insulating layer formation step S3 includes a microcapsule introduction step S31, an electrically insulating material application step S32, and an electrically insulating material hardening step S33. Electrically insulating material application step S32 is performed after microcapsule introduction step S31. Electrically insulating material hardening step S33 is performed after electrically insulating material application step S32.

In microcapsule introduction step S31, microcapsules are introduced into the unhardened electrically insulating material. The microcapsule is formed of an insulating resin material, and is filled with a volatile liquid.

In electrically insulating material application step S32, the electrically insulating material into which the microcapsules are introduced is applied on first surface 10a so as to cover first electrically conductive pattern 20 and is also applied on second surface 10b so as to cover second electrically conductive pattern 40.

In electrically insulating material hardening step S33, the electrically insulating material applied on first surface 10a and second surface 10b is heated and hardened to become first electrically insulating layer 30 and second electrically insulating layer 50, respectively. At this time, the liquid in the microcapsule is volatilized to form hollow microcapsule 32 and hollow microcapsule 52, thereby forming first void 31 and second void 51. Thus, printed wiring board 100 having the structure shown in FIGS. 1, 2, 3A and 3B is formed.

Although an example in which first electrically conductive pattern 20 and second electrically conductive pattern 40 are formed by a semi-additive method has been described above, first electrically conductive pattern 20 and second electrically conductive pattern 40 may be formed by a subtractive method.

Although first voids 31 and second voids 51 are formed by introducing the microcapsule filled with the liquid into the unhardened electrically insulating material in the above description, first voids 31 and second voids 51 may be formed by agitating the unhardened electrically insulating material to provide bubbles in the unhardened electrically insulating material.

(Effects of the Printed Wiring Board According to the Embodiment)

Hereinafter, effects of printed wiring board 100 will be described.

As the temperature of printed wiring board 100 increases, first electrically, insulating layer 30 (second electrically insulating layer 50) between adjacent portions of first electrically conductive pattern 20 (second electrically conductive pattern 40) may thermally expand, thereby warping printed wiring board 100.

However, in printed wiring board 100, since a plurality of first voids 31 (second voids 51) are present in first electrically insulating layer 30 (second electrically insulating layer 50), the effective elastic modulus and coefficient of thermal expansion of first electrically insulating layer 30 (second electrically insulating layer 50) are reduced. Therefore, according to printed wiring board 100, it is possible to suppress the warpage caused by a temperature rise.

When the elastic modulus and thermal conductivity of first electrically insulating layer 30 (second electrically insulating layer 50) are high, the warpage of printed wiring board 100 caused by a temperature rise becomes significant. According to printed wiring board 100, it is possible to suppress the warpage caused by a temperature rise even in such a case. In other words, according to printed wiring board 100, the heat resistance can be improved by using a material having a high elastic modulus and a high thermal conductivity (i.e., a material having high heat resistance) for first electrically insulating layer 30 (second electrically insulating layer 50).

The warpage of printed wiring board 100 due to the temperature rise becomes remarkable when the first pattern ratio and the second pattern ratio are different. In addition, when the aspect ratio of first electrically conductive pattern 20 (second electrically conductive pattern 40) is large, the warpage of printed wiring board 100 due to the temperature rise becomes remarkable. Further, when base film 10 is thin, the warpage of printed wiring board 100 due to the temperature rise becomes remarkable. According to printed wiring board 100, even in such a case, it is possible to suppress the warpage caused by a temperature rise.

(Simulation)

Hereinafter, a simulation performed to confirm the effect of printed wiring board 100 will be described. In this simulation, as shown in Table 1, samples 1 to 25 were used as samples of printed wiring board 100.

TABLE 1

| | First and Second Electrically Insulating Layers | | | | | | | |
|---|---|---|---|---|---|---|---|---|
| | Elastic | Thermal | | | | | | |
| | Modulus of | Conductivity | Area Ratio | First | Second | | | |
| | Constituent | of Constituent | of First | Pattern | Pattern | Height | Height | Amount of |
| | Material | Material | Voids | Ratio | Ratio | H1 | H2 | Warpage |
| | (GPa) | (K⁻¹) | (%) | (%) | (%) | (μm) | (μm) | (μm) |
| Sample 1 | 4 | 4.5 × 10⁻⁵ | 0 | 70 | 85 | 50 | 50 | 153.7 |
| Sample 2 | 4 | 4.5 × 10⁻⁵ | 5 | 70 | 85 | 50 | 50 | 141.0 |
| Sample 3 | 4 | 4.5 × 10⁻⁵ | 10 | 70 | 85 | 50 | 50 | 128.4 |
| Sample 4 | 4 | 4.5 × 10⁻⁵ | 20 | 70 | 85 | 50 | 50 | 103.3 |
| Sample 5 | 4 | 4.5 × 10⁻⁵ | 30 | 70 | 85 | 50 | 50 | 78.2 |
| Sample 6 | 4 | 4.5 × 10⁻⁵ | 0 | 50 | 65 | 50 | 50 | 149.5 |
| Sample 7 | 4 | 4.5 × 10⁻⁵ | 5 | 50 | 65 | 50 | 50 | 137.0 |
| Sample 8 | 4 | 4.5 × 10⁻⁵ | 10 | 50 | 65 | 50 | 50 | 124.6 |
| Sample 9 | 4 | 4.5 × 10⁻⁵ | 20 | 50 | 65 | 50 | 50 | 99.8 |
| Sample 10 | 4 | 4.5 × 10⁻⁵ | 30 | 50 | 65 | 50 | 50 | 75.2 |
| Sample 11 | 12 | 4.5 × 10⁻⁵ | 0 | 70 | 85 | 50 | 50 | 158.2 |
| Sample 12 | 12 | 4.5 × 10⁻⁵ | 5 | 70 | 85 | 50 | 50 | 145.5 |
| Sample 13 | 12 | 4.5 × 10⁻⁵ | 10 | 70 | 85 | 50 | 50 | 132.7 |
| Sample 14 | 12 | 4.5 × 10⁻⁵ | 20 | 70 | 85 | 50 | 50 | 107.2 |
| Sample 15 | 12 | 4.5 × 10⁻⁵ | 30 | 70 | 85 | 50 | 50 | 81.8 |
| Sample 16 | 4 | 9.0 × 10⁻⁵ | 0 | 70 | 85 | 50 | 50 | 400.6 |
| Sample 17 | 4 | 9.0 × 10⁻⁵ | 5 | 70 | 85 | 50 | 50 | 375.1 |
| Sample 18 | 4 | 9.0 × 10⁻⁵ | 10 | 70 | 85 | 50 | 50 | 349.6 |
| Sample 19 | 4 | 9.0 × 10⁻⁵ | 20 | 70 | 85 | 50 | 50 | 298.8 |
| Sample 20 | 4 | 9.0 × 10⁻⁵ | 30 | 70 | 85 | 50 | 50 | 248.1 |
| Sample 21 | 4 | 4.5 × 10⁻⁵ | 0 | 70 | 85 | 70 | 70 | 116.9 |
| Sample 22 | 4 | 4.5 × 10⁻⁵ | 5 | 70 | 85 | 70 | 70 | 107.4 |
| Sample 23 | 4 | 4.5 × 10⁻⁵ | 10 | 70 | 85 | 70 | 70 | 97.9 |
| Sample 24 | 4 | 4.5 × 10⁻⁵ | 20 | 70 | 85 | 70 | 70 | 78.9 |
| Sample 25 | 4 | 4.5 × 10⁻⁵ | 30 | 70 | 85 | 70 | 70 | 59.9 |

In samples 1 to 25, the elastic modulus of first electrically insulating layer 30 (the elastic modulus of the constituent material of first electrically insulating layer 30) and the elastic modulus of second electrically insulating layer 50 (the elastic modulus of the constituent material of second electrically insulating layer 50) were set to either 4 GPa or 12 GPa. Further, in the samples 1 to 25, the coefficient of thermal expansion of first electrically insulating layer 30 (the thermal conductivity of the constituent material of first electrically insulating layer 30) and the coefficient of thermal expansion of second electrically insulating layer 50 (the thermal conductivity of the constituent material of second electrically insulating layer 50) were either 4.5×10⁻⁵/K or 9.0×10⁻⁵/K.

In the samples 1 to 25, the area ratio of first void 31 in first electrically insulating layer 30 and the area ratio of second void 51 in second electrically insulating layer 50 were set to any one of 0 percent, 5 percent, 10 percent. 20 percent, and 30 percent.

In the samples 1 to 25, the first pattern ratio was set to either 50 percent or 70 percent, and the second pattern ratio was set to either 65 percent or 85 percent.

In the samples 1 to 25, height H1 and height H2 were set to either 50 μm or 70 μm. Although not shown in Table 1, in the samples 1 to 25, thickness T1 was 12.5 μm. The planar shape of each of the samples 1 to 25 was a 1 cm square.

For samples 1 to 25, the amount of warpage was calculated. The amount of warpage was defined as the distance between a reference surface and the position of the sample farthest from the reference surface when the sample was placed on a fiat reference surface. The amount of warpage was calculated by increasing the temperature of the sample by 50° C.

As shown in Table 1, the amount of warpage of sample 1 was larger than the amounts of warpage of samples 2 to 5, and the amount of warpage of sample 6 was larger than the amounts of warpage of samples 7 to 10. The amount of warpage of the sample 11 was larger than the amounts of warpage of the samples 12 to 15, and the amount of warpage of the sample 16 was larger than the amounts of warpage of the samples 17 to 20. The amount of warpage of the sample 21 was larger than the amounts of warpage of the samples 22 to 25.

In the sample 1, first void 31 was not present in first electrically insulating layer 30, and second void 51 was not present in second electrically insulating layer 50. Sample 1 was similar to samples 2 to 5 except for the area ratio of first void 31 in first electrically insulating layer 30 and the area ratio of second void 51 in second electrically insulating layer 50.

In the sample 6, first void 31 was not present in first electrically insulating layer 30, and second void 51 was not present in second electrically insulating layer 50. Sample 6 was similar to samples 7 to 10 except for the area ratio of first void 31 in first electrically insulating layer 30 and the area ratio of second void 51 in second electrically insulating layer 50.

In the sample 11, first void 31 was not present in first electrically insulating layer 30, and second void 51 was not present in second electrically insulating layer 50. Sample 11 was similar to samples 12 to 15 except for the area ratio of first void 31 in first electrically insulating layer 30 and the area ratio of second void 51 in second electrically insulating layer 50.

In sample 16, first void 31 was not present in first electrically insulating layer 30, and second void 51 was not present in second electrically insulating layer 50. Sample 16 was similar to samples 17 to 20 except for the area ratio of first void 31 in first electrically insulating layer 30 and the area ratio of second void 51 in second electrically insulating layer 50.

In the sample 21, first void 31 was not present in first electrically insulating layer 30, and second void 51 was not present in second electrically insulating layer 50. Sample 21 was similar to samples 22 to 25 except for the area ratio of first void 31 in first electrically insulating layer 30 and the area ratio of second void 51 in second electrically insulating layer 50.

From these comparisons, it has been found from simulations that the presence of first void 31 (second void 51) in first electrically insulating layer 30 (second electrically insulating layer 50) suppresses the warpage of printed wiring board 100 caused by a temperature rise.

It should be understood that the embodiments disclosed herein are illustrative in all respects and are not restrictive. The scope of the present invention is defined not by the embodiments described above but by the claims, and is intended to include all modifications within the meaning and scope equivalent to the claims.

### REFERENCE SIGNS LIST

10 base film, 10a first surface, 10b second surface, 10c through hole, 20 first electrically conductive pattern, 21 first seed layer, 22 first core body, 23 first shrink layer, 30 first electrically insulating layer, 31 first void, 32 microcapsule, 40 second electrically conductive pattern, 41 second seed layer, 42 second core body, 43 second shrink layer, 50 second electrically insulating layer, 51 second void, 52 microcapsule, 60 resist, 100 printed wiring board, H1, H2 height, S1 preparation step, S2 electrically conductive pattern formation step, S3 electrically insulating layer formation step, S21 seed layer formation step, S21a first layer formation step, S21b through hole formation step, S21c second layer formation step, S22 resist formation step, S23 first electrolytic plating step, S24 resist removal step, S25 seed layer removal step, S26 second electrolytic plating step, S31 microcapsule introduction step, S32 electrically insulating material application step, S33 electrically insulating material hardening step, T1 thickness, W2 width.

1. A printed wiring board comprising:
a base film having a first surface and a second surface opposite to the first surface;
a first electrically conductive pattern existing on the first surface; and
a first electrically insulating layer existing on the first surface so as to cover the first electrically conductive pattern,
wherein a plurality of first voids exist in the first electrically insulating layer.

2. The printed wiring board according to claim 1, wherein an area ratio of the plurality of first voids in the first electrically insulating layer in a sectional view is 3 percent or more.

3. The printed wiring board according to claim 1, wherein a coefficient of thermal expansion of the first electrically insulating layer is 3.0×10⁻⁵/K or more.

4. The printed wiring board according to claim 1, wherein an elastic modulus of the first electrically insulating layer is 2 GPa or more.

5. The printed wiring board according to claim 1, wherein the first electrically conductive pattern has a first seed layer existing on the first surface, a first core body existing on the first seed layer, and a first shrink layer covering the first core body.

6. The printed wiring board according to claim 1, wherein a height of the first electrically conductive pattern is larger than a width of the first electrically conductive pattern.

7. The printed wiring board according to claim 1, wherein a height of the first electrically conductive pattern is larger than a thickness of the base film.

8. The printed wiring board according to claim 1, wherein the first electrically conductive pattern has a spiral shape in a plan view.

9. The printed wiring board according to claim 1, further comprising:
a second electrically conductive pattern existing on the second surface; and
a second electrically insulating layer existing on the second surface so as to cover the second electrically conductive pattern,
wherein a plurality of second voids exist in the second electrically insulating layer, and
wherein a value obtained by dividing a total area of the first electrically conductive pattern by an area of the first surface in a plan view differs from a value obtained by dividing a total area of the second electrically conductive pattern by an area of the second surface in a plan view.

10. A method of manufacturing a printed wiring board, the method comprising:
preparing a base film having a first surface and a second surface opposite to the first surface;
forming a first electrically conductive pattern on the first surface; and
forming a first electrically insulating layer on the first surface so as to cover the first electrically conductive pattern,
wherein forming the first electrically insulating layer includes providing a plurality of first voids in the first electrically insulating layer.

11. The method of manufacturing a printed wiring board according to claim 10, wherein forming the first electrically insulating layer includes introducing a hollow microcapsule into an unhardened electrically insulating material, applying the electrically insulating material to the first surface so as to cover the first electrically conductive pattern, and heating and hardening the electrically insulating material.
